(19) United States
(12) Patent Application Publication
(10) Pub. No.: US 2008/0280073 A1
(43) Pub. Date: Nov. 13, 2008

(54) Substrate and Display Device

(75) Inventor: Kyoko Yamamoto, Ibaraki (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku (JP)

(21) Appl. No.: 11/911,536

(22) PCT Filed: Apr. 17, 2006
(86) PCT No.: PCT/JP06/08480

§ 371 Date: Oct. 15, 2007

(30) Foreign Application Priority Data
Apr. 18, 2005 (JP) 2005-119372

(51) Int. Cl. C09K 19/00; B32B 5/16; B05D 5/06

(52) U.S. Cl. 428/1.54; 428/480; 428/323; 427/64

(57) ABSTRACT

The present invention provides a substrate and a display device. The substrate comprises a resin layer 1 and a resin layer 2, wherein the resin layer 1 is composed of a liquid crystalline polyester A and a polymer B having a functional group reactive with a liquid crystalline polyester, and the resin layer 2 is composed of a resin other than a liquid crystalline polyester. The display device comprises the following (a) to (e) in that order: (a) the above-described resin layer 1, (b) the above-described resin layer 2, (c) electric conductive layer, (d) organic layer showing absorption, diffusion, optical rotation or emission of light by application of an electric field, and (e) transparent electric conductive layer.

### TECHNICAL FIELD

The present invention relates to a substrate and a display device. More particularly, the present invention relates to a display device such as a flexible display, and a substrate used for the same.

### BACKGROUND ART

Of display devices, flexible displays have flexibility and can be installed on a curved surface of equipments and the like, thus, paid to attention. As flexible displays, for example, organic EL devices and liquid crystalline devices are known.

As a substrate used in a display device, for example, a substrate including a base material, a gas barrier layer composed of an inorganic oxide, and a resin layer in that order is known (JP-A 2003-89163, pp. 1 to 3).

Display devices are required to have improved durability, and substrates used in display devices are required to have a high gas barrier property.

### DISCLOSURE OF THE INVENTION

The present inventors have intensively studied to solve the above-described problem, and resultantly completed the present invention.

That is, the present invention provides a substrate comprising a resin layer 1 and a resin layer 2,

wherein the resin layer 1 is composed of a liquid crystalline polyester, and the resin layer 2 is composed of a resin other than a liquid crystalline polyester.

Further, the present invention provides a display device comprising the following (a) to (e), in that order:

(a) the above-described resin layer 1,

(b) the above-described resin layer 2,

(c) electric conductive layer,

(d) organic layer showing absorption, diffusion, optical rotation or emission of light by application of an electric field, and

(e) transparent electric conductive layer.

### MODES FOR CARRYING OUT THE INVENTION

### Substrate

The substrate of the present invention contains a resin layer 1 and a resin layer 2. Though one resin layer 1 is usually used, two or more resin layers 1 may be used. One or more resin layers 2 may be used. Further, the substrate may contain a resin layer other than the resin layer 1 and the resin layer 2.

### [Resin Layer 1]

The resin layer 1 is composed of a liquid crystalline polyester, and substantially composed of a liquid crystalline polyester A and a polymer B having a functional group reactive with a liquid crystalline polyester.

### Liquid Crystalline Polyester A

The liquid crystalline polyester A includes, for example, those obtained by polymerizing an aromatic hydroxycarboxylic acid, aromatic dicarboxylic acid and aromatic diol, those obtained by polymerizing the same kind or different kinds of aromatic hydroxycarboxylic acids; those obtained by reacting a polyester such as polyethylene terephthalate or the like with an aromatic hydroxycarboxylic acid; and the like.

The liquid crystalline polyester A may be one which is obtained by using, instead of the aromatic hydroxycarboxylic acid, aromatic dicarboxylic acid and aromatic diol, ester formable derivatives thereof.

The ester formable derivatives of carboxylic acids include, for example, those in which a carboxylic group turns into a highly reactive derivative such as an acid chloride, acid anhydride or the like which promotes a polyester production reaction, those in which a carboxyl group forms an ester with alcohols, ethylene glycol and the like which generate a polyester by a transesterification reaction, and the like.

The aromatic hydroxycarboxylic acid, aromatic dicarboxylic acid and aromatic diol may be substituted by a halogen atom such as a chlorine atom, fluorine atom and the like, an alkyl group such as a methyl group, ethyl group and the like, an aryl group such as a phenyl group and the like.

Examples of repeating structural units of the liquid crystalline polyester include repeating structural units derived from aromatic dicarboxylic acids; repeating structural units derived from aromatic diols; and repeating structural units derived from aromatic hydroxycarboxylic acids.

Repeating Structural Units Derived from Aromatic Dicarboxylic Acids;

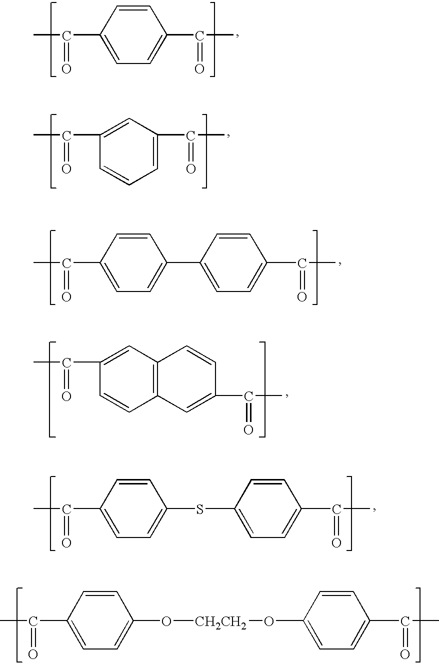

The above-described repeating structural unit may be substituted by a halogen atom, alkyl group or aryl group.

Repeating Structural Units Derived from Aromatic Diols;

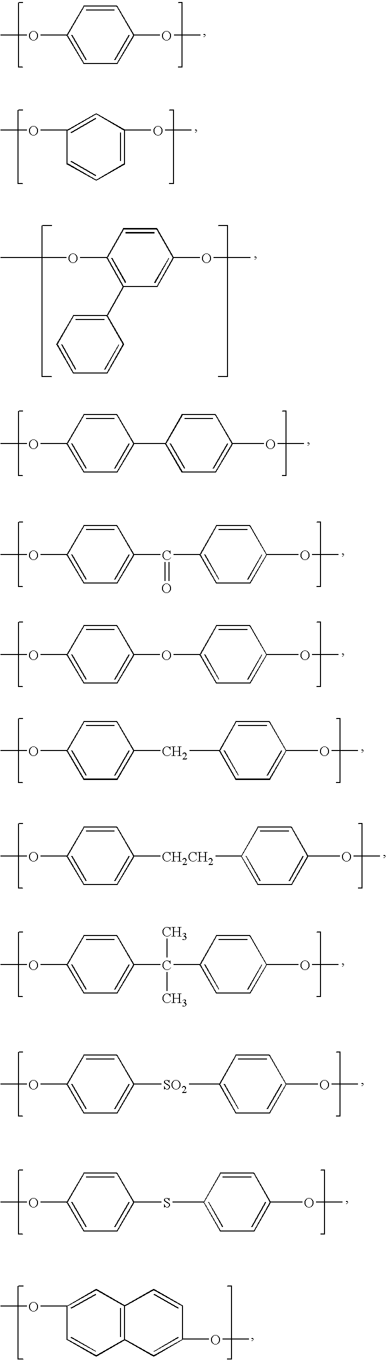

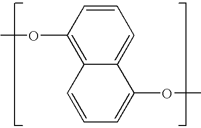

The above-described repeating structural unit may be substituted by a halogen atom, alkyl group or aryl group.

Repeating Structural Units Derived from Aromatic Hydroxycarboxylic Acids;

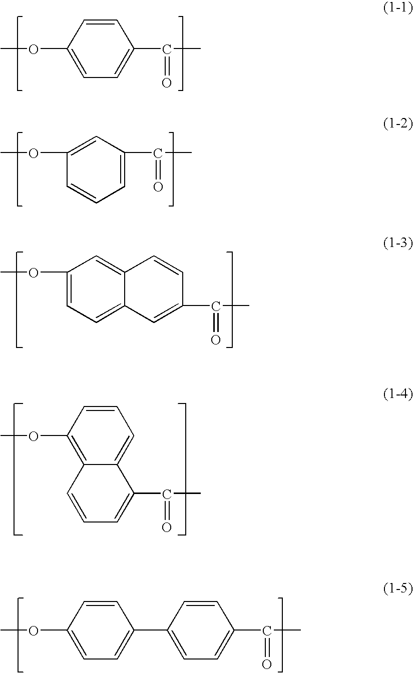

The above-described repeating structural unit may be substituted by a halogen atom, alkyl group or aryl group.

It is preferable that the liquid crystalline polyester A contains repeating structural units derived from aromatic dicarboxylic acids in an amount of 25 to 10 mol %, repeating structural units derived from aromatic diols in an amount of 35 to 10 mol %, and repeating structural units derived from aromatic hydroxycarboxylic acids in an amount of 30 to 80 mol %, from the standpoint of heat resistance of a substrate. The sum of these structural unit is 100 mol %.

It is preferable that the liquid crystalline polyester A contains a repeating structural unit represented by the formula (1-1) in an amount of not less than 30 mol % and not more than 99 mo % based on the total mol number of repeating structural units of the liquid crystalline polyester A from the standpoint of balance between heat resistance, mechanical property and processability of a substrate. The liquid crystalline polyester A having a repeating structural unit represented by the formula (1-1) has, as a repeating structural unit, usually the following (I), (II), (III), (IV), (V) or (VI), preferably (I), (TI), (III), (V) or (VI), further preferably (I), (II) or (III), particularly preferably (I) or (II).

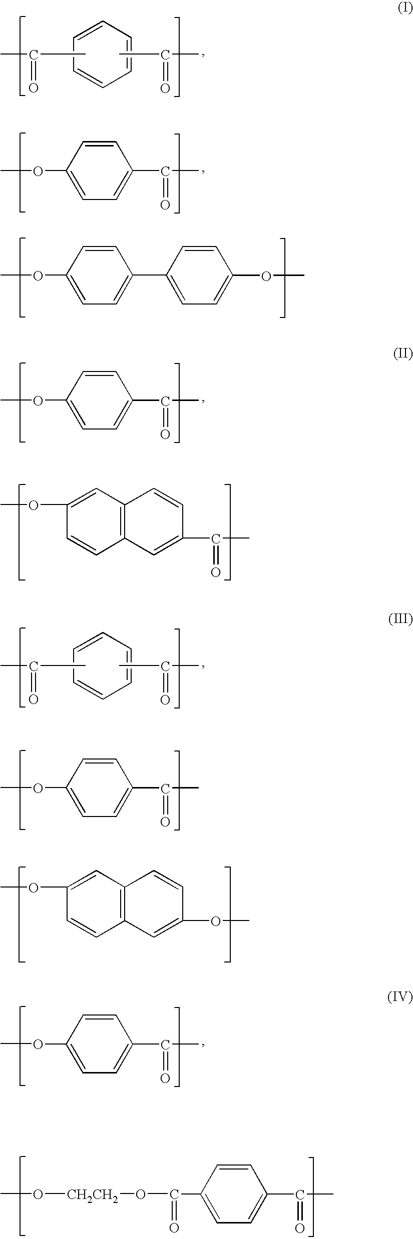

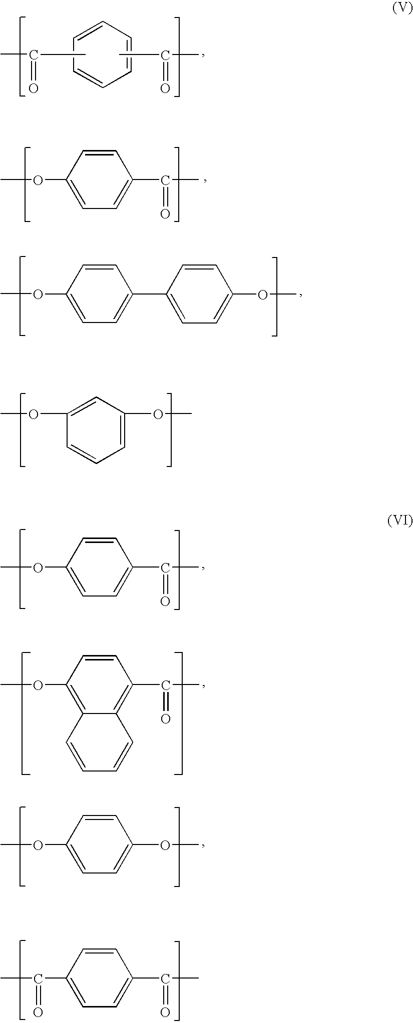

The liquid crystalline polyester A containing a repeating structural unit of any one of the formulae (I) to (VI) may be advantageously prepared according to methods described, for example, in JP-B 47-47870, JP-B 63-3888, JP-B 63-3891 and JP-B 56-18016, and JP-A 2-51523.

### Polymer B

The polymer B contains a functional group reactive with a liquid crystalline polyester. The functional group reactive with a liquid crystalline polyester is one which reacts with a liquid crystalline polyester, and is preferably an oxazolyl group, epoxy group or amino group, further preferably an epoxy group. These functional groups may exist as a part of other functional groups, and examples thereof include a glycidyl group and the like.

For introducing a functional group reactive with a liquid crystalline polyester into the polymer B, in the case of, for example, synthesis of a polymer, a monomer having the functional group may be polymerized, and alternatively, a monomer having the functional group may be graft-polymerized to a polymer. The monomer used in this case contains, for example, a glycidyl group. The monomer containing a glycidyl group is, preferably, an unsaturated glycidyl carboxylate or unsaturated glycidyl ether represented by the following formula:

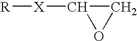

wherein, R represents a hydrocarbon group having 2 to 13 carbon atoms having an ethylenically unsaturated bond, and X represents —C(O)O—, —CH₂—O— or

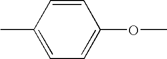

Examples of the unsaturated glycidyl carboxylate include glycidyl acrylate, glycidyl methacrylate, glycidyl itaconate, triglycidyl butenetricarboxylate, and glycidyl p-styrenecarboxylate.

Examples of the unsaturated glycidyl ether include vinyl glycidyl ether, allyl glycidyl ether, 2-methylallyl glycidyl ether, methacryl glycidyl ether, and styrene-p-glycidyl ether.

It is preferable that the polymer B contains an unsaturated glycidyl carboxylate unit and/or an unsaturated glycidyl ether unit in an amount of 0.1 to 30% by weight.

Examples of the polymer include a rubber and a thermoplastic resin having the above-described functional group. These may be used singly or in combination. The polymer B is preferably composed of rubber from the standpoint of thermal stability and flexibility of the resin layer 1.

When the polymer B is composed of rubber, in the case of, for example, synthesis of a rubber, a monomer having a functional group may be polymerized, and alternatively, a monomer having a functional group may be graft-polymerized to rubber.

Examples of the rubber include rubbers having an epoxy group such as (meth)acrylate-ethylene-(unsaturated glycidyl carboxylate and/or unsaturated glycidyl ether) polymer rubbers.

(Meth) acrylates are esters obtained from acrylic acid or methacrylic acid and alcohol. The alcohol is an alcohol having 1 to 8 carbon atoms. Examples of the (meth)acrylates include methyl acrylate, methyl methacrylate, n-butyl acrylate, n-butyl methacrylate, tert-butyl acrylate, tert-butyl methacrylate, 2-ethylhexyl acrylate, and 2-ethylhexyl methacrylate. The (meth)acrylates may be used singly or in combination.

In the polymer B, the content of (meth)acrylate units in the rubber is usually over 40% by weight, preferably not less than 45% by weight and usually less than 97% by weight, preferably not more than 70% by weight, the content of an ethylene unit is usually not less than 3% by weight, preferably not less than 10% by weight and usually less than 50% by weight, preferably not more than 49% by weight, and the content of unsaturated glycidyl carboxylate units and/or unsaturated glycidyl ether units is usually not less than 0.1% by weight, preferably not less than 0.5% by weight and usually not more than 30% by weight, preferably not more than 20% by weight, from the standpoint of thermal stability and mechanical property. The sum of them is 100% by weight

The rubber may be advantageously produced by, for example, bulk polymerization, emulsion polymerization or solution polymerization using a free radical initiator. The rubber may be advantageously prepared under conditions of a pressure of not less than 500 kg/cm² and a temperature of 40 to 300° C. in the presence of a polymerization initiator generating a free radical, as described in JP-A 48-11388 and JP-A 61-127709.

The polymer B may also be a rubber having a functional group other than those described above. Examples of the other rubbers include acrylic rubbers having a functional group reactive with a liquid crystalline polyester, and vinyl aromatic hydrocarbon compound-conjugated diene compound block copolymer rubbers having a functional group reactive with a liquid crystalline polyester.

The acrylic rubber is preferably a polymer of a monomer represented by the formula (2-1), (2-2) or (2-3):

CH₂═CH—C(O)—OR¹ (2-1)

CH₂═CH—C(O)—OR²OR³ (2-2)

CH₂═C⁴H—C(O)—O(R⁵(C(O)O)ₙR⁶ (2-3)

wherein, R¹ represents an alkyl group or cyanoalkyl group having 1 to 18 carbon atoms. R² represents an alkylene group having 1 to 12 carbon atoms, and R³ represents an alkyl group having 1 to 12 carbon atoms R⁴ represents a hydrogen atom or methyl group, R⁵ represents an alkylene group having 3 to 30 carbon atoms, R⁶ represents an alkyl group having 1 to 20 carbon atoms or its derivative, and n represents an integer of 1 to 20. These monomers may be used singly or in combination.

The alkyl acrylate represented by the formula (2-1) is, for example, methyl acrylate, ethyl acrylate, propyl acrylate, butyl acrylate, pentyl acrylate, hexyl acrylate, octyl acrylate, 2-ethylhexyl acrylate, nonyl acrylate, decyl acrylate, dodecyl acrylate or cyanoethyl acrylate.

The alkoxyalkyl acrylate represented by the formula (2-2) is, for example, methoxyethyl acrylate, ethoxyethyl acrylate, butoxyethyl acrylate or ethoxypropyl acrylate.

The acrylic rubber may contain these compounds singly or in combination.

The acrylic rubber may be a mixture of unsaturated monomers copolymerizable with at least one selected from compounds represented by the formulae (2-1) to (2-3), or a copolymer thereof.

Examples of the unsaturated monomers include styrene, α-methylstyrene, acrylonitrile, halogenated styrene, methacrylonitrile, acrylonitrile, methacrylamide, vinylnaphthalene, N-methylolacrylamide, vinyl acetate, vinyl chloride, vinylidene chloride, benzyl acrylate, methacrylic acid, itaconic acid, fumaric acid and maleic acid.

The acrylic rubber is a copolymer, for example, of 40 to 99.9% by weight of at least one monomer selected from compounds represented by the formulae (2-1) to (2-3), 0.1 to 30% by weight of an unsaturated glycidyl carboxylate and/or unsaturated glycidyl ether, and 0 to 30% by weight of an unsaturated monomer copolymerizable with at least one selected from compounds represented by the formulae (2-1) to (2-3). The sum of them is 100% by weight. If the acrylic rubber satisfies the above-described formulation, the resin layer 1 gets excellent heat resistance, impact resistance, and molding processability.

The acrylic rubber may be advantageously prepared by emulsion polymerization, suspension polymerization, solution polymerization or bulk polymerization in the presence of a radical initiator, for example, as described in JP-A 59-113010, 62-64809 and 3-160008 and WO95/04764.

Examples of the vinyl aromatic hydrocarbon compound-conjugated diene compound block copolymer rubber include rubbers obtained by epoxidation of a block copolymer containing a sequence composed mainly of a vinyl aromatic hydrocarbon compound and a sequence composed mainly of a conjugated diene compound, and rubbers obtained by epoxidation of a hydrogenated substance of a block copolymer.

Examples of the vinyl aromatic hydrocarbon compound include styrene, vinyltoluene, divinylbenzene, α-methylstyrene, p-methylstyrene and vinylnaphthalene, and preferable is styrene.

Examples of the conjugated diene compound include butadiene, isoprene, 1,3-pentadiene and 3-butyl-1,3-octadiene, and preferable are butadiene and isoprene.

The vinyl aromatic hydrocarbon compound-conjugated diene compound block copolymer or its hydrogenated substance may be advantageously prepared, for example, by methods described in JP-B 40-23798 and JP-A 59-133203.

It is preferable that the polymer B contains a (meth)acrylate-ethylene-(unsaturated glycidyl carboxylate and/or unsaturated glycidyl ether) copolymer rubber.

The polymer B may be vulcanized. Vulcanization of a (meth)acrylate-ethylene-(unsaturated glycidyl carboxylate and/or unsaturated glycidyl ether) copolymer rubber may be advantageously carried out using, for example, a polyfunctional organic acid, polyfunctional amine compound or imidazole compound.

When the polymer B is a thermoplastic resin, the thermoplastic resin preferably has an epoxy group. The thermoplastic resin is an epoxy group-containing ethylene copolymer, for example, having a content of an ethylene unit of not less than 50% by weight and not more than 99% by weight, a content of an unsaturated glycidyl carboxylate unit and/or unsaturated glycidyl ether unit of not less than 0.1% by weight, preferably not less than 0.5% by weight and not more than 30% by weight, preferably not more than 20% by weight, and a content of an ethylenically unsaturated ester compound unit of not less than 0% by weight and not more than 50% by weight. The sum of these units is 100% by weight.

Examples of the ethylenically unsaturated ester compound include vinyl carboxylates such as vinyl acetate, vinyl propionate, methyl acrylate, ethyl acrylate, butyl acrylate, methyl methacrylate, ethyl methacrylate, butyl methacrylate and the like; and alky α,β-unsaturated carboxylates, and preferable are vinyl acetate, methyl acrylate and ethyl acrylate.

Examples of the epoxy group-containing ethylene copolymer include a copolymer composed of an ethylene unit and a glycidyl methacrylate unit, a copolymer composed of an ethylene unit, glycidyl methacrylate unit and methyl acrylate unit, a copolymer composed of an ethylene unit, glycidyl methacrylate unit and ethyl acrylate unit, and a copolymer composed of an ethylene unit, glycidyl methacrylate unit and vinyl acetate unit. The epoxy group-containing ethylene copolymer may be advantageously prepared usually by a high pressure radical polymerization method (an unsaturated epoxy compound and ethylene are copolymerized in the presence of a radical initiator at 500 to 4000 atm and 100 to 300° C. in the presence or absence of a suitable solvent or chain transfer agent). The epoxy group-containing ethylene copolymer may also be prepared by a method in which an unsaturated epoxy compound and radical initiator are mixed with polyethylene, and they are subjected to melt graft copolymerization in an extruder.

It is preferable that the resin layer 1 contains the liquid crystalline polyester A as a continuous phase and the polymer B as a dispersed phase. The resin layer 1 satisfying this condition has a high gas barrier property and heat resistance.

In the resin layer 1, the content of the liquid crystalline polyester A is usually not less than 56 parts by weight, preferably not less than 65 parts by weight, further preferably not less than 70 parts by weight and usually not more than 99.9 parts by weight, preferably not more than 98 parts by weight, and the content of polymer B is usually not less than 0.1 parts by weight, preferably not less than 2 parts by weight and usually not more than 44 parts by weight, preferably not more than 35 parts by weight, further preferably not more than 30 parts by weight.

The resin layer 1 satisfying this condition has a high water vapor barrier property and heat resistance.

The resin layer 1 may be advantageously prepared, for example, by kneading the liquid crystalline polyester A and the polymer B. Kneading may be advantageously carried out using an apparatus such as a single screw or twin screw extruder or single screw or twin screw kneader, preferably a twin screw kneader. Kneading may be advantageously carried out under condition of a cylinder set temperature of the apparatus of 200 to 360° C., preferably 230 to 350° C.

It may also be permissible that, before kneading, the liquid crystalline polyester A and polymer B are uniformly mixed previously by an apparatus such as a tumbler or Henschel mixer, and the mixture is supplied to an apparatus and kneaded. Alternatively, it may also be permissible that the liquid crystalline polyester A and polymer B are separately fed to an apparatus each quantitatively, and kneaded.

In preparation of the resin layer 1, various additives such as organic fillers, antioxidants, thermal stabilizers, photostabilizers, flame retardants, lubricants, antistatic agents, inorganic or organic coloring agents, anticorrosive agents, cross-linking agents, foaming agents, fluorescent agents, surface lubricating agents, surface gloss improvers, mold release improvers such as a fluorine resin and the like, may also be used, if necessary. It is advantageous that the additives are added in kneading the liquid crystalline polyester A and polymer B, or in the subsequent step (for example, molding).

The resin layer 1 is prepared preferably by inflation molding which is capable of performing biaxially oriented simultaneously. The resin layer 1 may be advantageously prepared, for example, by feeding a mixture of the liquid crystalline polyester A and polymer B to an extruder with a die of circular slit, melt-kneading the mixture under condition of a cylinder set temperature of 200 to 360° C., preferably 230 to 350° C., extruding the molten resin upwardly or downwardly from the cyclic slit of the extruder, next, cooling the circumference of the swollen resin with air or water, then, taking off the resin through nip rolls. The extruding direction (longitudinal direction) is the MD direction, and a direction crossing the MD direction in film plane is the TD direction. The lip clearance is usually not less than 0.1 mm, preferably not less than 0.5 mm and usually not more than 5 mm, preferably not more than 2 mm, and the diameter of the cyclic slit is usually not less than 20 mm, preferably not less than 50 mm and usually not more than 1000 mm, preferably not more than 300 mm. The blow ratio of inflation molding is usually 1.5 to 10, and the draw down ratio is usually 1.5 to 40. If molded under this condition, a resin layer 1 having uniform thickness, showing no wrinkle and having high strength is obtained. Inflation molding may be advantageously carried out while selecting condition for swelling of the molten resin into uniform thickness with smooth surface, according to the formulation of the resin.

The resin layer 1 has a thickness of usually not less than 3 μm, preferably not less than 5 μm, further preferably not less than 8 μm and usually less than 500 μm, preferably less than 300 μm, further preferably less than 200 μm, from the standpoint of satisfaction of an excellent gas barrier property and flexibility.

### [Resin Layer 2]

The resin layer 2 is composed of a resin other than a liquid crystalline polyester. The resin layer 2 is composed of a heat resistant resin, and for example, composed of a resin having a glass transition temperature (Tg) of not lower than 150° C., preferably not lower than 180° C., further preferably not lower than 190° C. Examples of the resin layer 2 include polyolefins such as an ethylene-norbornene copolymer, ethylene-dimethanooctahydronaphthalene (DMON) copolymer and the like; polyesters such as polyethylene terephthalate, polybutylene terephthalate, polyethylene naphthalate and the like; nylon-6, nylon-6,6 metaxylenediamine-adipic acid polycondensate; amide resins such as polymethylmethacrylimide and the like; acrylic resins such as polymethyl methacrylate and the like; styrene-acrylonitrile resins such as polystyrene, styrene-acrylonitrile copolymer, styrene-acrylonitrile-butadiene copolymer, polyacrylonitrile and the like; hydrophobicized cellulose resins such as cellulose triacetate, cellulose diacetate and the like; halogen-containing resins such as polyvinyl chloride, polyvinylidene chloride, polyvinylidene fluoride, polytetrafluoroethylene and the like; hydrogen bonding resins such as polyvinyl alcohol, ethylene-vinyl alcohol copolymer, cellulose derivatives and the like; and polycarbonates, polysulfones, polyether sulfones, polyether ether ketones, polyphenyleneoxides and polymethylene oxides, and of these resins, an ethylene-norbornene copolymer, ethylene-DMON copolymer, polyethylene naphthalate, polycarbonates, polysulfones and polyether sulfones are mentioned. These may be used singly or in combination.

The resin layer 2 has a thickness of usually not less than 3 μm, preferably not less than 5 μm, further preferably not less than 8 μm and usually less than 500 μm, preferably less than 300 μm, further preferably less than 200 μm.

The resin layer 2 has an average surface roughness Ra of usually not more than 5 nm, preferably not more than 3 nm. The average surface roughness Ra corresponds to arithmetic average roughness described in JIS B 0601 (revised on Jan. 20, 2001), paragraph [4.2.1] published by Japanese Standard Association, and obtained from an average line of a profile curve of the surface of the resin layer 2. Measurement of the average surface roughness Ra may be advantageously carried out using a commercially available apparatus.

### [Inorganic Layer 3]

It is preferable that the substrate further contains an inorganic layer 3.

Examples of the inorganic layer 3 include metals (aluminum, copper, nickel and the like), metal oxides (silica, alumina, titania, indium oxide, tin oxide, titanium oxide, zinc oxide and the like), metal nitrides (aluminum nitride, silicon nitride and the like), metal carbides (silicon carbide and the like), metal oxynitrides (silicon oxynitride and the like), preferably, alumina, aluminum nitride, silicon nitride, silicon oxynitride, further preferably, silicon oxynitride. These may be used singly or in combination.

The inorganic layer 3 has a thickness of usually not less than 1 nm, preferably not less than 10 nm and usually not more than 100 nm, preferably not more than 500 nm.

It is preferable that the inorganic layer 3 is in contact with the resin layer 2.

### [Inorganic Layered Compound-Containing Resin Layer 4]

The substrate may further contain an inorganic layered compound-containing resin layer 4.

The layer 4 contains a resin C and an inorganic layered compound. The resin C is usually a resin having high heat resistance, and examples thereof include polyolefins such as an ethylene-norbornene copolymer, ethylene-DMON copolymer and the like; polyesters such as polyethylene terephthalate, polybutylene terephthalate, polyethylene naphthalate and the like; nylon-6, nylon-6,6 metaxylenediamine-adipic acid polycondensate, amide resins such as polymethylmethacrylimide and the like; acrylic resins such as polymethyl methacrylate and the like; styrene-acrylonitrile resins such as polystyrene, styrene-acrylonitrile copolymer, styrene-acrylonitrile-butadiene copolymer, polyacrylonitrile and the like; hydrophobicized cellulose resins such as cellulose triacetate, cellulose diacetate and the like; halogen-containing resins such as polyvinyl chloride, polyvinylidene chloride, polyvinylidene fluoride, polytetrafluoroethylene and the like; hydrogen bonding resins such as polyvinyl alcohol, ethylene-vinyl alcohol copolymer, cellulose derivatives and the like; and polycarbonates, polysulfones, polyether sulfones (hereinafter, referred to as “PES”), polyether ether ketones, polyphenyleneoxides and polymethylene oxides These may be used singly or in combination.

The inorganic layered compound is usually a clay mineral. Examples of the clay mineral include kaolinite, dickite, nacrite, halloysite, antigorite, chrysotile, pyrophylite, montmorillonite, hectorite, tetra-silicic mica, sodium taeniolite, white mica, margarite, talc, vermiculite, bronze mica, xanthophyllite and chlorite, preferably, kaolinite, montmorillonite, hectrite and talc.

The inorganic layered compound has an average particle size L of usually not less than 50 nm, preferably not less than 100 nm and usually not more than 5 μm, preferably not more than 3 μm, further preferably not more than 2 μm. The average particle size L is measured by a dynamic light scattering method in a solvent.

The inorganic layered compound has an aspect ratio of usually not less than 50, preferably not less than 100 and usually not more than 5000, preferably not more than 2000, further preferably not more than 1000. The aspect ratio Z is calculated by the formula: Z=L/a. L is an average particle size, and a is an average value of unit thicknesses calculated from diffraction peaks of the inorganic layered compound obtained by powder X-ray diffraction measurement.

Further, in the inorganic layered compound, it is preferable that planes having relatively larger area among particle planes (for example, when the inorganic layered compound is a plate particle, planes vertical to the thickness direction of the plate) are so oriented (hereinafter, referred to as “oriented along plane direction”) as to be approximately parallel to a plane vertical to the thickness direction of the inorganic layered compound-containing resin layer 4.

The inorganic layered compound-containing resin layer 4 has a weight ratio of the inorganic layered compound to the resin (inorganic layered compound/resin) of 5 parts by weight/95 parts by weight to 90 parts by weight/10 parts by weight, preferably 5 parts by weight/95 parts by weight to 50 parts by weight/50 parts by weight.

The inorganic layered compound-containing resin layer 4 has a thickness of usually not less than 0.01 μm, preferably not less than 0.1 μm and usually not more than 5 μm, preferably not more than 3 μm.

The inorganic layered compound-containing resin layer 4 may be in contact with the resin layer 1.

### [Electric Conductive Layer 5]

The substrate may further contain an electric conductive layer 5.

The electric conductive layer 5 contains an inorganic substance or organic substance having conductivity. Examples of the inorganic substance having conductivity include metal oxides (indium oxide, zinc oxide, tin oxide, indium.tin.oxide (ITO), indium.zinc.oxide and the like), and metals (gold, platinum, silver, copper and the like). The electric conductive layer 5 composed of an inorganic substance may be advantageously formed, for example, by a vacuum vapor deposition, sputtering, ion plating, or plating. Examples of the organic substance having conductivity include polyaniline or derivatives thereof, and polythiophene or derivatives thereof. The electric conductive layer 5 may be in contact with the resin layer 2, further, may be patterned. The electric conductive layer may be used also as a positive electrode or negative electrode of a display device.

The electric conductive layer 5 has a thickness of usually not less than 0-05 μm, preferably not less than 0.1 μm and usually not more than 0.5 μm, preferably not more than 0.4 μm.

The substrate of the present invention contains a resin layer 1 and a resin layer 2, and contains optionally an inorganic layer 3, an inorganic layered compound-containing resin layer 4 and an electric conductive layer 5, and the lay structure of the substrate is, for example,

(L1) resin layer 1/resin layer 2,

(L2) resin layer 1/resin layer 2/inorganic layer 3,

(L3) resin layer 1/inorganic layered compound-containing resin layer 4/resin layer 2, or

(L4) resin layer 1/inorganic layered compound-containing resin layer 4/resin layer 2/inorganic layer 3.

The substrate may contain a antireflection layer or abrasion resistant layer.

Further, the substrate may contain a layer containing additives such as an ultraviolet absorber, colorant, antioxidant and the like, and the resin layer 1, resin layer 2, inorganic layer 3, inorganic layered compound-containing resin layer 4, electric conductive layer 5, reflection preventing layer and abrasion resistance layer may contain additives.

The substrate has a high gas barrier property, and its water vapor permeability is usually 0.2 g/m²/day, preferably not more than 0.1 g/m²/day, and its oxygen permeability is usually not more than 0.1 cc/m²/day, preferably not more than 0.05 cc/m²/day. The substrate has an average linear thermal expansion coefficient in the temperature range of 20° C. to 150° C. of usually not less than −10 ppm/° C., preferably not less than −5 ppm/° C. and usually not more than 25 ppm/° C., preferably not more than 20 ppm/° C.

The substrate having the above-described layer structure (L1) may be advantageously produced, for example, by a method including the step (1a) or step (1b).

(1a) forming a resin layer 2 on a resin layer 1 by means of coating.

(1b) laminating a resin layer 2 onto a resin layer 1.

The substrate having the layer structure (L2) may be advantageously produced, for example, by a method including the steps of (1a) and (2a), or steps of (1b) and (2a)

(2a) forming an inorganic layer 3 on a resin layer 2.

The substrate having the layer structure (L3) may be advantageously produced, for example, by a method including the steps of (3a) and (3c), steps of (3a) and (3d), steps of (3b) and (3c), or steps of (3b) and (3d).

(3a) forming an inorganic layered compound-containing resin layer 4 on a resin layer 1 by means of coating,

(3b) laminating and an inorganic layered compound-containing resin layer 4 onto a resin layer 1,

(3c) forming a resin layer 2 on an inorganic layered compound-containing resin layer 4 by means of is formed by coating,

(3d) laminating a resin layer 2 onto an inorganic layered compound-containing resin layer 4.

The substrate having the layer structure (L4) may be advantageously produced, for example, by a method including the steps of (3a), (3c) and (2b), steps of (3a), (3d) and (2a), steps of (3b), (3c) and (2a), or steps of (3b), (3d) and (2a).

Coating may be advantageously carried out by applying, drying and thermally treating a coating liquid containing a resin contained in the resin layer 2 or the inorganic layered compound-containing resin layer 4, and may be advantageously carried out, for example, by a direct gravure, reverse gravure, micro gravure, roll coating (twin roll beat coating, bottom feed triple reverse coating and the like), doctor knife, die coating, dip coating, or bar coating. These may be used singly or in combination. Usually, the coating liquid contains a solvent.

When the inorganic layered compound-containing resin layer 4 is formed, the solvent is preferably that which swells and cleaves the inorganic layered compound to provide a dispersion, and preferable are, for example, water, alcohols (methanol and the like), dimethylformamide, dimethyl sulfoxide, dichloromethane, chloroform, toluene, acetone and N-methylpyrrolidone. In this case, the coating liquid may be advantageously produced by a method 1 in which a solution prepared by dissolving the above-described resin C in a solvent, and a dispersion are mixed, a method 2 in which a dispersion and a resin are mixed, a method 3 in which an inorganic layered compound is added to a solution and mixed while swelling and cleaving, or a method 4 in which the resin C and an inorganic layered compound are melt-kneaded to obtain a kneaded substance which is then mixed with a solvent, preferably by the method 1, 2 or 3. From the standpoint of improvement of the dispersibility of an inorganic layered compound, the inorganic layered compound may be subjected to a surface treatment previously. The surface treatment agent is, for example, a quaternary ammonium salt.

Lamination may also be carried out after surface treatment of a surface at which the resin layer 1, resin layer 2 and inorganic layered compound-containing resin layer 4 are pasted, from the standpoint of improvement of adhesion. Examples of the surface treatment include a corona discharge treatment, plasma treatment, flame treatment, sputtering treatment, solvent treatment, ultraviolet ray treatment, polishing treatment, infrared treatment and ozone treatment.

Formation of the inorganic layer 3 and electric conductive layer 5 may be advantageously carried out by a vacuum vapor deposition, CVD, sputtering or sol-gel method.

### Display Device

The display device of the present invention contains the above-described substrate, and usually contains the following (a) to (e) in that order.

(a) resin layer 1,

(b) resin layer 2,

(c) electric conductive layer,

(d) organic layer manifesting at least one function selected from absorption, diffusion, rotation and emission of light by application of an electric field, and

(e) transparent electric conductive layer.

The resin layer 1 is composed of the same material as for the resin layer 1 of the above-described substrate.

The resin layer 2 is composed of the same material as for the resin layer 2 of the above-described substrate.

The electric conductive layer is composed of the same material as for the electric conductive layer 5 of the above-described substrate.

The organic layer may be advantageously one showing a function of absorption, diffusion, optical rotation and emission of light by application of an electric field.

That showing a function of light absorption by application of an electric field is, for example, a liquid crystalline composition containing a dichroic dye.

That showing a function of light diffusion by application of an electric field is, for example, a polymer dispersed liquid crystal.

That showing a function of light rotation by application of an electric field is, for example, a cholesteric liquid crystalline mixture.

That showing a function of light emission by application of an electric field, namely, a light emitting layer is composed of a low molecular weight compound or polymer compound, and preferably composed of a polymer compound from the standpoint of easiness of application. Examples of the low molecular weight compound include naphthalene derivatives, anthracene or derivatives thereof, perylene or derivatives thereof, polymethine, xanthenes, coumarine and cyanine coloring matters and the like, metal complexes of 8-hydroxyquinoline or derivatives thereof, aromatic amines, tetraphenylcyclopentadiene or derivatives thereof, and tetraphenylbutadiene or derivatives thereof, as described in JP-A 57-51781 and JP-A 59-194393. Examples of the polymer compound include poly(p-phenylenevinylene), polyfluorene (Jpn. J. Appl. Phys.), vol. 30, p. L1941 (1991)), poly-p-phenylene derivatives (Adv Mater., vol. 4, p. 36 (1992)).

The light emitting layer may be advantageously formed, for example, by a vapor deposition using a powder of a low molecular weight compound or polymer compound, a method of applying a solution of a low molecular weight compound or polymer compound and drying it, an inkjet or a spin coating.

In the light emitting layer, an electron transport layer and/or hole transport layer may be combined.

The hole transport layer is composed of, for example, polyvinyl carbazole or derivatives thereof, polysilane or derivatives thereof, polysiloxane derivatives having an aromatic amine compound group on the side chain or main chain, polyaniline or derivatives thereof, polythiophene or derivatives thereof, poly(p-phenylenevinylene) or derivatives thereof, or poly(2,5-thienylenevinylene) or derivatives thereof. The hole transport layer may be advantageously formed by a method in which these compounds and a polymer binder are mixed, and the resultant solution is applied and dried.

The electron transport layer is composed of, for example, oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, metal complexes of 8-hydroxyquinoline or derivatives thereof, polyquinoline or derivatives thereof, polyquinoxaline or derivatives thereof, or polyfluorene or derivatives thereof. The electron transport layer may be advantageously formed by a vapor deposition using a powder of these compounds, or a method by applying a solution of these compounds and drying this.

The transparent electric conductive layer is a layer having transparency and electric conductivity, and may be patterned. The transparent electric conductive layer may be advantageously formed, for example, by a vapor deposition, CVD, sputtering or sol-gel method. The patterned transparent electric conductive layer may be advantageously formed by sputtering or resist work using a mask.

When the electric conductive layer is used as a negative electrode of a display device, a transparent electric conductive layer is used as a positive electrode. In this case, the transparent electric conductive layer is composed of, for example, a metal or organic substance, and for example, composed of a metal oxide such as indium oxide, zinc oxide, tin oxide, indium.tin.oxide (ITO) or indium.zinc.oxide, or a metal such as gold, platinum, silver or copper. The transparent electric conductive layer may be advantageously formed, for example, by a vacuum vapor deposition, sputtering, ion plating or plating. The transparent electric conductive layer may also be composed of an organic substance such as polyaniline or derivatives thereof, and polythiophene or derivatives thereof.

On the other hand, when the electric conductive layer is used as a positive electrode of a display device, a transparent electric conductive layer is used as a negative electrode. In this case, the transparent electric conductive layer is composed, for example, of a metal such as lithium, sodium, potassium, rubidium, cesium, beryllium, magnesium, calcium, strontium, barium, aluminum, scandium, vanadium, zinc, yttrium, indium, cerium, samarium, europium, terbium or ytterbium, an alloy of two or more of these metals, an alloy of at least one of these metals and at least one selected from gold, silver, platinum, copper, manganese, titanium, cobalt, nickel, tungsten and tin, or graphite or graphite interlaminar compound. The transparent electric conductive layer may be advantageously formed, for example, by a vacuum vapor deposition, sputtering or thermocompression bonding. The transparent electric conductive layer may have layer thickness decreased from the standpoint of improvement of transparency. Further, the transparent electric conductive layer may be a laminate layer composed of a material to be a positive electrode from the standpoint of lowering of resistance value.

Examples of the layer structure of the display device include:

resin layer 1/resin layer 2/positive electrode (electric conductive layer)/light emitting layer/negative electrode (transparent electric conductive layer)

resin layer 1/resin layer 2/positive electrode (electric conductive layer)/light emitting layer/electron transport layer/negative electrode (transparent electric conductive layer)

resin layer 1/resin layer 2/positive electrode (electric conductive layer)/hole transport layer/light emitting layer/negative electrode (transparent electric conductive layer)

resin layer 1/resin layer 2/positive electrode (electric conductive layer)/hole transport layer/light emitting layer/electron transport layer/negative electrode (transparent electric conductive layer)

resin layer 1/resin layer 2/negative electrode (electric conductive layer)/light emitting layer/positive electrode (transparent electric conductive layer)

resin layer 1/resin layer 2/negative electrode (electric conductive layer)/electron transport layer/light emitting layer/positive electrode (transparent electric conductive layer)

resin layer 1/resin layer 2/negative electrode (electric conductive layer)/light emitting layer/hole transport layer/positive electrode (transparent electric conductive layer), and

resin layer 1/resin layer 2/negative electrode (electric conductive layer)/electron transport layer/light emitting layer/hole transport layer/positive electrode (transparent electric conductive layer).

Preferably mentioned are, resin layer 1/resin layer 2/positive electrode (electric conductive layer)/hole transport layer/light emitting layer/electron transport layer/negative electrode (transparent electric conductive layer), and resin layer 1/resin layer 2/negative electrode (electric conductive layer)/electron transport layer/light emitting layer/hole transport layer/positive electrode (transparent electric conductive layer).

The display device usually contains a laminate composed of the above-described layer structure and an sealant, a part or all of the laminate being encapsulated.

The sealant is composed of a material having transparency, preferably having transparency and impacting sufficient flexibility to the resultant display device. Examples of the sealant include polyolefins such as polyethylenes (low density, high density), ethylene-propylene copolymers, ethylene-butene copolymers, ethylene-hexene copolymers, ethylene-octene copolymers, ethylene-norbornene copolymers, ethylene-DMON copolymers, polypropylene, ethylene-vinyl acetate copolymers, ethylene-methyl methacrylate copolymers, ionomer resins and the like; polyesters such as polyethylene terephthalate, polybutylene terephthalate, polyethylene naphthalate and the like; nylon-6, nylon-6,6, metaxylenediamine-adipic acid polycondensate; amide resins such as polymethylmethacrylimide and the like; acrylic resins such as polymethyl methacrylate and the like; styrene-acrylonitrile resins such as polystyrene, styrene-acrylonitrile copolymer, styrene-acrylonitrile-butadiene copolymer, polyacrylonitrile and the like; hydrophobicized cellulose resins such as cellulose triacetate, cellulose diacetate and the like; halogen-containing resins such as polyvinyl chloride, polyvinylidene chloride, polyvinylidene fluoride, polytetrafluoroethylene and the like; hydrogen bonding resins such as polyvinyl alcohol, ethylene-vinyl alcohol copolymer, cellulose derivatives and the like; and engineering plastic resins such as polycarbonates, polysulfones, polyethersulfones, polyether ether ketones, polyphenylene oxides, polymethylene oxides and the like. The sealant is in the form of film, and has a thickness of usually not less than 20 μm and not more than 1000 μm, preferably not more than 500 μm, further preferably not more than 300 μm.

Encapsulation may be advantageously carried out by coating or lamination. The coating method is a method in which coating liquid containing the above-described sealant is applied on a laminate, and dried and thermally treated, and may be advantageously carried out, for example, by a direct gravure, reverse gravure, micro gravure, roll coating (for example, twin roll beat coating, bottom feed triple reverse coating), doctor knife, die coating, dip coating, or bar coating. These may be used singly or in combination.

The lamination is a method of bonding a laminate with a sealant in the form of film. In the lamination, a corona treatment or a treatment with an anchor coat agent may be carried out on a surface to be bonded.

Further, the display device may have a protective layer for the purpose of protecting a transparent electric conductive layer. The protective layer may be advantageously formed usually before encapsulation with a sealant.

The display device of the present invention has flexibility, and has a more excellent gas barrier property, and is used suitably in a flexible display. The flexible display is used, for example, in computer, television, portable terminal, cellular telephone, car navigation, and view finder of video camera. The display device is suitably used as a sheet light source for backlight of a liquid crystalline display, or as a light source for illumination in the form of sheet since the display device is of self emitting type and can be made thinner.

Further, the display device may be so fabricated as to cause light emission in various patterns, by changing the arrangement and shape of a positive electrode and a negative electrode. For example, when a light emission in the form of sheet is obtained, a sheet anode and a sheet cathode may be advantageously arranged so as to overlap. When a light emission in the form of specific pattern is obtained, it may be advantageous that a mask having a window in the form of its specific pattern is placed on the surface of a sheet display device, or either an anode or cathode, or both the electrodes are formed in the form of specific pattern. By forming a pattern by any of these methods and arranging some electrodes so that ON/OFF is possible independently, a display device of segment type capable of displaying numbers, letters, simple marks and the like is obtained. In the case of a dot matrix device, it may be advantageous that both an anode and a cathode are formed in the form of stripe and arranged so as to cross. When a method for painting a plurality of light emitting layers of different emission colors separately is used or a color filter or fluorescence converting filter is used, partial color display and multi color display are made possible. The dot matrix display may be passively driven, or actively driven in combination with TFT and the like.

The display device may be advantageously produced, for example, by a method including the steps of (a′) to (d′) according to the order of the above-described layer structure.

(a′) forming a resin layer 2 on a resin layer 1,

(b′) forming an electric conductive layer 5 on the resin layer 2,

(c′) forming an organic layer showing absorption, diffusion, optical rotation and emission of light by application of an electric field on the electric conductive layer 5,

(e) forming a transparent electric conductive layer on the organic layer.

The display device having an electron transport layer and hole transport layer may be advantageously produced, for example, by a method including the steps of (a′), (b′), (e1′), (c1′) and (d′) in that order, a method including the steps of (a′), (b′), (c′), (f1′) and (d1′) in that order, or a method including the steps of (a′), (b′), (e1′), (c1′), (f1′) and (d1′) in that order. Here, (a′), (b′) and (d′) are the same as described above, and (e1′) is a step of forming an electron transport layer on a layer formed by the steps of (b′), (c1′) is a step of forming an organic layer showing absorption, diffusion, optical rotation or emission of light by application of an electric field on a layer formed in the prior step, (f1′) is a step of forming a hole transport layer on the layer formed in the prior step, (d1′) is a step of forming a transparent electric conductive layer on a layer formed in the prior step.

The display device containing a sealant contains further the following step of (g′).

All or a part of a laminate (composed of resin layer 1, resin layer 2, electric conductive layer, organic layer and transparent electric conductive layer, and if necessary, electron transport layer, hole transport layer) is encapsulated with a sealant.

### EXAMPLES

The present invention is described in more detail by following Examples, which should not be construed as a limitation upon the scope of the present invention.

### Surface Roughness Ra:

Ra was measured using Nanopics manufactured by Seiko Instruments.

### Production Example 1 of Liquid Crystalline Polyester Layer (Resin Layer 1)

### [Preparation of Liquid Crystalline Polyester A]

16.6 kg (12.1 mol) of p-hydroxybenzoic acid, 8.4 kg (4.5 mol) of 6-hydroxy-2-naphthoic acid and 18.6 kg (18.2 mol) of acetic anhydride were charged in a polymerization vessel with a comb-shaped stirring blade, and heated under a nitrogen gas atmosphere while stirring, and polymerized for 1 hour at 320° C., further, for 1 hour at 320° C. under a reduced pressure of 2.0 torr. During this procedure, acetic acid by-produced was distilled out of the system continuously. Thereafter, the mixture was cooled gradually, and taken out at 180° C., to obtain a polymer.

The polymer was ground by a hammer mill manufactured by Hosokawa Micron K.K., to obtain particles having a particle size of not more than 2.5 mm, then, thermally treated at 240° C. for 5 hours in a rotary kiln under a nitrogen atmosphere, to obtain a liquid crystalline polyester A. The liquid crystalline polyester A was in the form of particle, had repeating units in a ratio shown below, and a flow initiation temperature of 270° C.

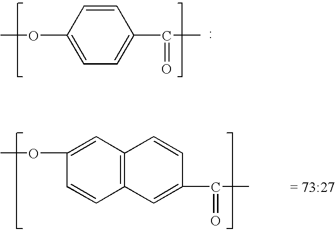

The liquid crystalline polyester A showed optical anisotropy at not lower than 280° C. under pressure as a result of observation using a polarization microscope.

### [Preparation of Polymer B]

A rubber of methyl acrylate/ethylene/glycidyl methacrylate=59.0/38.7/2.3 (ratio by weight) was obtained according to a method described in JP-A 61-127709, Example 5.

### [Formation of Liquid Crystalline Polyester Layer (Resin Layer 1)]

A liquid crystalline polyester A (95% by weight) and a polymer B (5% by weight) were melt-kneaded using TEX-30 type twin screw extruder manufactured by Japan Steel Works, Ltd. under conditions of a cylinder set average temperature of 300° C. and a screw rotating speed of 250 rpm, to obtain a composition. The composition showed optical anisotropy at not lower than 265° C. under pressure.

The composition was melt-kneaded using a single screw extruder with an inner diameter of 60 mmφ, having a cylindrical die with a diameter of 50 mm under conditions of a cylinder set temperature of 290° C., a screw rotating speed of 60 rpm, a lip clearance of 1.0 mm and a die set temperature of 305° C., to obtain a cylindrical molten resin, and dry air was pressed into a hollow space of this cylindrical molten resin to cause swelling thereof, then, the resin was cooled, then, passed through nip rolls to obtain a liquid crystalline polyester. The blow ratio was 2.5, the draw down ratio was 10, and the average thickness of the liquid crystalline polyester layer was 40 μm.

The liquid crystalline polyester layer had an average surface roughness (Ra) of 8.6 nm (10 μm). The results of evaluation of the gas barrier property (water vapor permeability at 40° C., oxygen permeability at 23° C.) of the liquid crystalline polyester layer were shown in Table 2.

### Comparative Example 1

On a PES film having a thickness of 200 μm, a silicon oxynitride layer having a thickness of 150 nm was formed by sputtering, to obtain a substrate 1. The layer structure of the substrate 1 was shown in Table 1, and the evaluation results of the gas barrier property thereof were shown in Table 2.

### Example 1

Into a 100 mL three-necked flask equipped with a three-way stopcock and Dimroth condenser in a side tube and with a fluorine resin stirring blade in a main tube was charged 15 g of PES (trade name: “PES5200p”, manufactured by Sumitomo Chemical Co., Ltd., Tg: 230° C.) and 45 g of N-methylpyrrolidone, and the mixture was stirred at 80° C. for 3 hours, to obtain coating liquid for formation of resin layer 2.

On the liquid crystalline polyester layer described above, the coating liquid for formation of resin layer 2 was applied using a bar coater (“SA-203 type”, manufactured by Tester Sangyo K.K.), to form a PES layer (resin layer 2) having a thickness of 15 μm, to obtain a substrate 2 having flexibility. The substrate 2 had an average surface roughness (Ra) of the PES layer of 0.2 nm (10 μm) and an average linear thermal expansion coefficient in the temperature range of 20° C. to 150° C. of −1.8 ppm/° C.

### Example 2

On the substrate 2 obtained in Example 1, an Al₂O₃ layer (inorganic layer 3) having a thickness of 150 nm was formed by sputtering under condition of 120° C., obtaining a substrate 3 having flexibility. The layer structure of the substrate 3 was shown in Table 1, and the evaluation results of the gas barrier property thereof were shown in Table 2.

### Example 3

Into 3000 g of ion exchanged water was added 100 g of polyvinyl alcohol (trade name “PVA117H”, manufactured by Kuraray Co., Ltd.) and the mixture was heated up to 95° C. under stirring condition (blade rotating speed: 1500 rpm, blade peripheral velocity: about 4 m/sec.), and further stirred for 1 hour to cause dissolution thereof, obtaining a solution. The solution was cooled down to 65° C. while stirring, and alcohol water (mixture of 1600 g of ion exchanged water and 376 g of 1-butanol) was dropped into the coating liquid. After completion of dropping, 50 g of natural montmorillonite of high purity (trade name “Kunipia G”, manufactured by Kunimine Kogyo K.K., appearance: powder, aspect ratio: 200 to 1000) was added at 65° C. as an inorganic layered compound to the solution, and the mixture was stirred under stirring conditions (blade rotating speed: 3000 rpm, blade peripheral velocity: about 8 m/sec.) for 90 minutes to cause dispersion, obtaining mixed liquid. The mixed liquid was passed through an ultrahigh pressure homogenizer (“M110-E/H type”, manufactured by Microfluidics Corporation) under condition of 1.750 kgf/cm², to obtain coating liquid for formation of inorganic layered compound-containing resin layer.

On the liquid crystalline polyester layer described above, the coating liquid for formation of inorganic layered compound-containing resin layer was applied using a bar coater (“SA-203 type”, manufactured by Tester Sangyo K.K.), and dried and thermally treated to form an inorganic layered compound-containing layer 4 having a thickness of 1.4 μm, obtaining a substrate 4.

On the substrate 4, the coating liquid for formation of resin layer 2 prepared in Example 1 was applied using a bar coater (“SA-203 type”, manufactured by Tester Sangyo K.K.), and dried and thermally treated to form a PES layer (resin layer 2) having a thickness of 15 μm, obtaining a substrate 5 having flexibility. The substrate 5 had an average surface roughness (Ra) of the PES layer of 1.7 nm (10 μm) and an average linear thermal expansion efficient in the temperature range of 20° C. to 150° C. of −1.1 ppm/° C.

### Example 4

On the substrate 5 obtained in Example 3, an Al₂O₃ layer (inorganic layer 3) having a thickness of 150 nm was formed by sputtering under condition of 120° C., obtaining a substrate 6 having flexibility. The layer structure of the substrate 6 was shown in Table 1, and the evaluation results of the gas barrier property thereof were shown in Table 2.

### Example 5

On the substrate 2 obtained in Example 3, a SiON layer having a thickness of 150 nm was formed by sputtering under condition of 120° C., obtaining a substrate 7 having flexibility. The layer structure of the substrate 7 was shown in Table 1, and the evaluation results of the gas barrier property thereof were shown in Table 2.

TABLE 1
Layer structure of substrate

| | Layer structure |
|---|---|
| Production Example 1 | Resin layer 1 (LCP) |
| Comparative | Resin layer 2 (PES)/inorganic layer 3 |
| Example 1 | (SiON) |
| Example 1 | Resin layer 1 (LCP)/Resin layer 2 (PES) |
| Example 2 | Resin layer 1 (LCP)/Resin layer 2 |
| | (PES)/inorganic layer 3 (Al₂O₃) |
| Example 3 | Resin layer 1 (LCP)/inorganic layered |
| | compound-containing resin layer |
| | 4/resin layer 2 (PES) |
| Example 4 | Resin layer 1 (LCP)/inorganic layered |
| | compound-containing resin layer |
| | 4/resin layer 2 (PES)/inorganic layer |
| | 3 (Al₂O₃) |
| Example 5 | Resin layer 1 (LCP)/Resin layer 2 |
| | (PES)/inorganic layer 3 (SiON) |

TABLE 2
Gas barrier property of substrate

| | | Water vapor | Oxygen |
|---|---|---|---|
| | | permeability | permeability |
| | | at 40° C. | at 23° C. |
| | | [g/m²/day] | [cc/m²/day] |
| Production | Resin layer 1 | 0.29 | 0.84 |
| Example 1 | | | |
| Comparative | Substrate 1 | 0.60 | 2.9 |
| Example 1 | | | |
| Example 2 | Substrate 3 | 0.12 | <0.01 |
| Example 4 | Substrate 6 | 0.16 | <0.01 |
| Example 5 | Substrate 7 | 0.22 | <0.01 |

### INDUSTRIAL APPLICABILITY

The substrate of the present invention has flexibility, and has more excellent gas barrier property, thus, used suitably for display devices such as flexible displays and lighting.

Further, the display device of the present invention has flexibility and gas barrier property, and is excellent in durability.

1. A substrate comprising a resin layer 1 and a resin layer 2, wherein the resin layer 1 is composed of a liquid crystalline polyester A and a polymer B having a functional group reactive with a liquid crystalline polyester, and the resin layer 2 is composed of a resin other than a liquid crystalline polyester.

2. The substrate according to claim 1, wherein the weight ratio of the liquid crystalline polyester A to the polymer B in the resin layer 1 (liquid crystalline polyester A/polymer B) is 56 to 99.9 parts by weight/44 to 0.1 parts by weight.

3. The substrate according to claim 1, wherein the resin layer 1 is in contact with the resin layer 2.

4. The substrate according to claim 1, wherein the resin layer 2 has an average surface roughness Ra of not more than 6 nm.

5. The substrate according to claim 1, wherein the resin layer 2 is composed of a resin having a glass transition temperature Tg of not lower than 150° C.

6. The substrate according to claim 1, wherein the substrate further comprises an inorganic layer 3.

7. The substrate according to claim 6, wherein the inorganic layer 3 is composed of at least one selected from the group consisting of metals, metal oxides, metal nitrides, metal carbides and metal oxynitrides.

8. The substrate according to claim 6, wherein the inorganic layer 3 is in contact with the resin layer 2.

9. The substrate according to claim 1, wherein the substrate further comprises a layered inorganic compound-containing resin layer 4.

10. The substrate according to claim 9, wherein the layered inorganic compound-containing resin layer 4 contains a layered inorganic compound having an average particle size of not more than 5 μm and an aspect ratio of 50 to 500.

11. The substrate according to claim 9, wherein the layered inorganic compound-containing resin layer 4 is in contact with the resin layer 1.

12. The substrate according to claim 1, wherein the substrate further comprises an electric conductive layer 5.

13. The substrate according to claim 12, wherein the electric conductive layer 5 is in contact with the resin layer 2.

14. The substrate according to claim 1, wherein the average linear thermal expansion coefficient in the temperature range of 20° C. to 150° C. is −10 ppm/° C. to 25 ppm/° C.

15. A display device comprising the following (a) to (e) in that order:
(a) said resin layer 1,
(b) said resin layer 2,
(c) electric conductive layer,
(d) organic layer showing absorption, diffusion, optical rotation or emission of light by application of an electric field, and
(e) transparent electric conductive layer.

16. The display device according to claim 15, wherein the display device further comprises a sealant which encapsulates a part or all of a laminate composed of said (a) to (e).

17. The display device according to claim 15, wherein the display device is a flexible display.

18. A method for producing a display device, comprising the steps of
(a′) forming a resin layer 2 on a resin layer 1,
(b′) forming an electric conductive layer 5 on the resin layer 2,
(c′) forming an organic layer showing absorption, diffusion, optical rotation or emission of light by application of an electric field, on the electric conductive layer 5, and
(d′) forming a transparent electric conductive layer on the organic layer.

19. The production method according to claim 18, further comprising the step of
(g′) encapsulating all or a part of a laminate composed of the resin layer 1, the resin layer 2, the electric conductive layer, the organic layer and the transparent electric conductive layer with a sealant.

20. Use of the substrate according to claim 1 as a display device.
